(19) United States
(12) Patent Application Publication
(10) Pub. No.: US 2013/0127295 A1
(43) Pub. Date: May 23, 2013

(54) PIEZOELECTRIC MICRO POWER GENERATOR AND FABRICATION METHOD THEREOF

(71) Applicant: Electronics and Telecommunications Research, Daejeon (KR)

(72) Inventors: Chi Hoon JUN, Daejeon (KR); Sang Choon KO, Daejeon (KR); Kwang-Seong CHOI, Daejeon (KR)

(73) Assignee: Electronics and Telecommunications Research Institute, Daejeon (KR)

(21) Appl. No.: 13/660,402

(22) Filed: Oct. 25, 2012

(30) Foreign Application Priority Data
Nov. 21, 2011 (KR) 10-2011-0121523

(51) Int. Cl. H02N 2/18; H01L 21/02; B82Y 99/00

(52) U.S. Cl. 310/327; 438/50; 977/948; 977/762; 977/742; 257/E21.002

(57) ABSTRACT

Disclosed are a piezoelectric micro power generator which converts mechanical energy to electric energy to produce electric power and a fabrication method thereof. The piezoelectric micro power generator according to an exemplary embodiment of the present disclosure includes a piezoelectric structure having a silicon base, a lower electrode formed on the silicon base, a piezoelectric film formed on the lower electrode and configured to generate electric energy in response to a change of mechanical strain, an upper electrode formed on the piezoelectric film and a proof mass coupled to a portion of a bottom surface of the silicon base and configured to control response characteristics to vibration frequency, and a frame having an opened cavity of a predetermined size and coupled to a portion of the bottom surface of the silicon base such that the proof mass is located within the cavity so as to suspend the piezoelectric structure.

### CROSS-REFERENCE TO RELATED APPLICATIONS

This application is based on and claims priority from Korean Patent Application No. 10-2011-0121523, filed on Nov. 21, 2011, with the Korean Intellectual Property Office, the disclosure of which is incorporated herein in its entirety by reference.

### TECHNICAL FIELD

The present disclosure relates to a piezoelectric micro power generator which converts mechanical energy generated in a surrounding environment to electric energy to produce electric power by itself, and a method of manufacturing the same.

### BACKGROUND

In general, a battery of a sensor needs to be periodically replaced so that electric power is supplied from the battery mounted in the sensor and then the entire sensor needs to be detached and attached again, and thus problems such as repair costs, lifespan of batteries, high temperatures and environmental contaminations occur. Accordingly, in recent years, a demand on a self-powered sensor which generates electric power and is operated by itself instead of an external power source including a battery or a domestic power source is increasing. As wireless sensors are becoming ultra-small sized and intelligent, a micro power generator capable of supplying electric power to the wireless sensors while being coupled in the form of a module are being required to be developed.

In particular, when used in an environment where mechanical energy such as vibrations normally exist, that is, a vehicle tire, a motor, a railway, an air conditioning system, or a machine tool, a micro power generator can show a great effect. For example, if a tire pressure monitoring system (TPMS) which is a wireless sensor module for monitoring a pressure state of a vehicle tire in real time is installed together with a micro power generator, mechanical movements of the tire can be changed to electric energy to operate the wireless sensor module without using an external power supply unit.

As a method of using a piezoelectric material as an energy converting material, a piezoelectric micro power generator for changing mechanical energy, such as vibrations, an impact, a rotating force, an inertial force, a pressure and a fluid flow, which is generated in the surrounding environment, into electric energy, uses characteristics of producing electric charges when a strain is changed in a piezoelectric material including an inorganic material such as ceramic or an organic material such as a polymer to achieve a simple conversion method and obtain a high output voltage and easily realize a structure without using an external voltage source.

The power generator using such a piezoelectric material includes a piezoelectric body and electrodes, and collects electric charges produced by a change of mechanical strain applied to the piezoelectric body in the electrodes, producing electric energy by itself.

The piezoelectric micro power generator according to the related art has been mainly realized through a method of cutting and attaching a ceramic-sintered piezoelectric body to a mechanical structure or a metal plate which can cause a mechanical displacement in the form of a patch or forming a thick film piezoelectric material in a material, such as a polymer material or polydimethylsiloxane (PDMS), whose stiffness is relatively low. However, these are methods for mechanically machining and assembling various types of structures, and thus manufacturing costs increase.

Meanwhile, in recent years, studies on a small-sized piezoelectric micro power generator mainly utilizing a microelectromechanical system (MEMS) technology to which a silicon semiconductor process is applied are being conducted. Such a piezoelectric micro power generator is fabricated by repeatedly performing processes of thin film deposition, application of a photosensitive film, micro patterning, and thin film etching to sequentially stack the above-mentioned functional elements in a direction perpendicular to a substrate. According to the methods, ten or more pattern masks are used to form the main functional elements. Thus, high manufacturing costs and a long period are required and a yield rate deteriorates during a fabrication process.

In the piezoelectric micro power generator structure, a proof mass performs primary functions in a frequency response to an external vibration and power generating characteristics, and it is advantageous in an aspect of miniaturization of elements to form the proof mass with a material such as tungsten having a high density as illustrated in a material property of Table 1. In particular, the silicon proof mass fabricated through a batch silicon process has a low density, and thus the micro power generator using the same is difficult to response to an external low vibration frequency and vulnerable to an impact. Accordingly, a fabrication method by which various frequency bands are utilized as a power source by easily using various materials as proof masses is necessary.

TABLE 1

| Material | Density (g/cm³) |
|---|---|
| Tungsten | 19.6 |
| Copper | 8.93 |
| SST | 7.48~8.0 |
| Si | 2.33 |

In order to operate the micro power generator, a moved part needs to be separated from a substrate, and thus when a silicon-on-insulator (SOI) wafer which is a high-priced substrate is used to easily separate the moving part, manufacturing costs further increase. In detail, an etched pit or a groove is formed by micromachining a rear surface of a silicon substrate, and a suspended structure separated from the substrate together with the proof mass is fabricated. The final separation step generally uses a sacrificial layer releasing process for releasing a silicon oxide film existing below a silicon structure through a wet and dry process using hydrofluoric acid (HF) or anhydrous HF, and a structure is often damaged by an unbalance of a stress, a surface tension, an impact and the like during the above step, a step of treating the suspended structure at a wafer level and a step of coupling a device to a package, causing yield rate to be lowered.

### SUMMARY

The present disclosure has been made in an effort to provide a silicon based piezoelectric micro power generator which can be mass-produced with a simple structure, easily employ various types of materials as a proof mass, and easily couple a piezoelectric structure of the micro power generator onto a package, and a method of manufacturing the same.

An exemplary embodiment of the present disclosure provides a piezoelectric micro power generator, including: a piezoelectric structure having a silicon base, a lower electrode formed on the silicon base, a piezoelectric film formed on the lower electrode and configured to generate electric energy in response to a change of mechanical strain, an upper electrode formed on the piezoelectric film and a proof mass coupled to a portion of a bottom surface of the silicon base and configured to control response characteristics to vibration frequency; and a frame having an opened cavity of a predetermined size and coupled to a portion of the bottom surface of the silicon base such that the proof mass is located within the cavity so as to suspend the piezoelectric structure.

The piezoelectric structure may be formed in the form of a cantilever by coupling only one portion of the bottom surface of the silicon base to the frame, or may be formed in the form of a bridge by coupling two portions of the bottom surface of the silicon base to the frame.

Another exemplary embodiment of the present disclosure provides a piezoelectric micro power generator, including: a piezoelectric structure array including a plurality of piezoelectric structures, each having a silicon base, a lower electrode formed on the silicon base, a piezoelectric film formed on the lower electrode and configured to generate electric energy in response to a change of mechanical strain, an upper electrode formed on the piezoelectric film and a proof mass coupled to a portion of a bottom surface of the silicon base and configured to control response characteristics to vibration frequency; and a frame having opened cavities of a predetermined size and coupled to portions of the bottom surfaces of the silicon bases of the plurality of piezoelectric structures such that a plurality of proof masses coupled to the plurality of piezoelectric structures is located within the cavities so as to suspend the piezoelectric structure array.

Yet another exemplary embodiment of the present disclosure provides a method of manufacturing a piezoelectric micro power generator, including: forming an insulation film on a silicon substrate; sequentially forming a lower electrode, a piezoelectric film and an upper electrode on the insulation film; polishing a bottom surface of the silicon substrate to form a silicon base; forming a die separating recess on the bottom surface of the silicon base to divide the silicon base; coupling a proof mass to a portion of the bottom surface of the silicon base; coupling a portion of the bottom surface of the silicon base to a top surface of the frame having an opened cavity such that the proof mass is located within the cavity; and separating the silicon base for dies by using the die separating recess.

According to the exemplary embodiments of the present disclosure, a piezoelectric micro power generator whose manufacturing costs are inexpensive with a simple structure can be realized through a silicon based semiconductor process, a polishing process, and a bonding process.

Various types of materials may be coupled to a proof mass, and thus a piezoelectric micro power generator where external vibrations can be efficiently used as a power generating source and having a miniaturized structure can be realized.

As a piezoelectric structure and a frame may be coupled to each other, a piezoelectric micro power generator which reduces manufacturing costs and simplifies a process can be realized.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1A is a plan view of a piezoelectric micro power generator in the form of a cantilever according to an exemplary embodiment of the present disclosure.

FIG. 1B is a sectional view illustrating section C-C′ of FIG. 1A.

FIG. 2A is a plan view of a piezoelectric micro power generator in the form of a bridge according to an exemplary embodiment of the present disclosure.

FIG. 2B is a sectional view illustrating section C-C′ of FIG. 2A.

FIG. 3 is a plan view of a piezoelectric micro power generator 100 including a plurality of piezoelectric structures 190 in the form of a cantilever array according to another exemplary embodiment of the present disclosure.

FIG. 4 is a plan view of a piezoelectric micro power generator 100 including a plurality of piezoelectric structures 190 in the form of a bridge array according to another exemplary embodiment of the present disclosure.

FIGS. 5 to 10 are process flowcharts illustrating a method of manufacturing a piezoelectric micro power generator according to an exemplary embodiment of the present disclosure.

FIG. 11 is a view illustrating electric power characteristics according to external vibration frequency of a cantilever-type piezoelectric micro power generator according to an exemplary embodiment of the present disclosure by using an output voltage.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

The above-described objects, characteristics, and advantages will be described in detail hereinbelow with reference to the accompanying drawings, and thus those skilled in the art to which the present disclosure pertains can easily carry out the technical spirit of the present disclosure. In a description of the present disclosure, a detailed description of known technologies related to the present disclosure will be omitted when it may make the gist of the present disclosure unnecessarily obscure. Hereinafter, exemplary embodiments of the present disclosure will be described in detail with reference to the accompanying drawings.

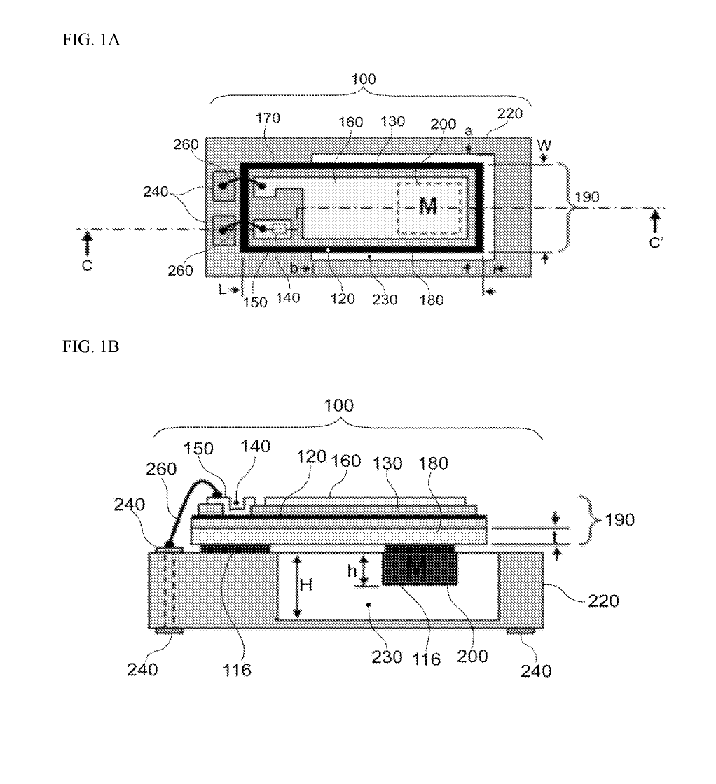

FIG. 1A is a plan view of a piezoelectric micro power generator in the form of a cantilever according to an exemplary embodiment of the present disclosure, and FIG. 1B is a sectional view illustrating section C-C′ of FIG. 1A.

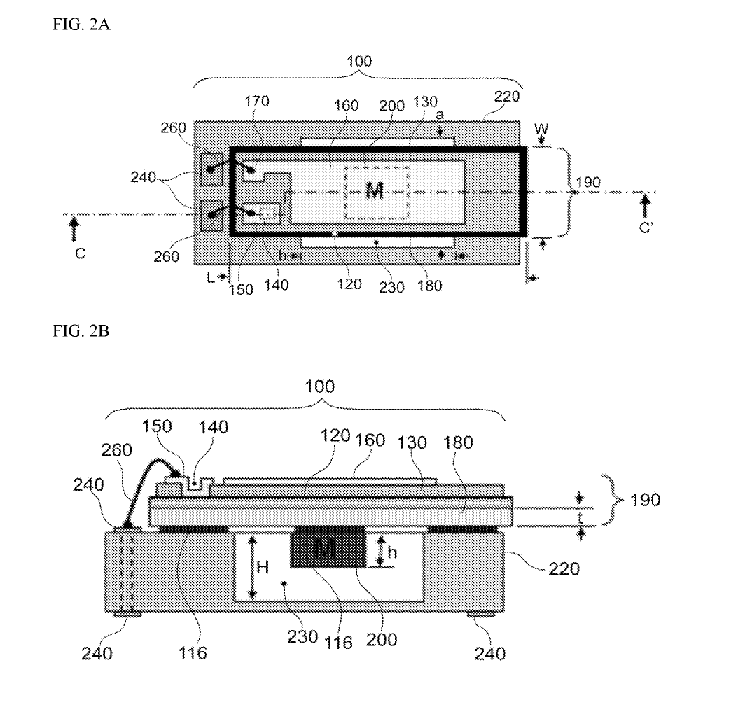

FIG. 2A is a plan view of a piezoelectric micro power generator in the form of a bridge according to an exemplary embodiment of the present disclosure, and FIG. 2B is a sectional view illustrating section C-C′ of FIG. 2A.

Referring to FIGS. 1A to 2B, a piezoelectric micro power generator 100 according to the present disclosure includes a piezoelectric structure 190 having a silicon base 180, a lower electrode 120 formed on the silicon base 180, a piezoelectric film 130 formed on the lower electrode 120 and configured to generate electric energy in response to a change of mechanical strain, an upper electrode 160 formed on the piezoelectric film 130 and a proof mass 200 coupled to a portion of a bottom surface of the silicon base 180 and configured to control response characteristics to vibration frequency, and a frame 220 having an opened cavity 230 of a predetermined size and coupled to a portion of the bottom surface of the silicon base 180 such that the proof mass 200 is located within the cavity 230 so as to suspend the piezoelectric structure 190. The piezoelectric micro power generator 100 further includes a lower electrode pad 150 and an upper electrode pad 170 ends of which are connected to the lower electrode 120 and the upper electrode 160, respectively and configured to transfer electric energy collected by the two electrodes 120 and 160 to the outside.

Here, the piezoelectric structure 190 may be formed in the form of a cantilever where only one portion of the bottom surface of the silicon base 180 is coupled to the frame 220 as illustrated in FIGS. 1A and 1B, or may be formed in the form of a bridge where two portions of the bottom surface of the silicon base 180 are coupled to the frame 220 as illustrated in FIGS. 2A and 2B.

The silicon base 180 which is a basic support body of the piezoelectric structure 190 has predetermined width W, length L and thickness t.

The frequency response to external vibrations is mainly determined according to the width W, length L and thickness t (for example, not more than 100 μm) of the silicon base 180 and a mass M and an attaching location of the proof mass 200. In particular, frequency characteristics may be varied by controlling the mass M of the proof mass 200, and if the proof mass 200 is formed of a heavy metallic material such as tungsten, it is possible to implement the piezoelectric micro power generator 100 having a low frequency response characteristic even with a small size. A material of the proof mass 200 includes at least one of an inorganic material, an organic material, and a mixture thereof.

The frame 220 suspends the piezoelectric structure 190, and when external vibrations occur, allows the piezoelectric structure 190 to be mechanically displaced freely in response to the external vibrations. The frame 220 may be formed to have the opened cavity 230 having the predetermined width a, length b, and depth H to restrict a maximum displacement of the piezoelectric structure 190 to which the proof mass 200 is attached. In general, the proof mass 200 is designed to sufficiently move in response to external vibrations by making the height H of the frame 220 larger than the height h of the proof mass 200. The frame 220 may be formed of at least one of a printed circuit board (PCB), ceramic, glass, metal, plastic, a silicon material, and a mixture thereof, and a plurality of electrical wire extracting parts 240 may be formed on the top surface of the frame 220 such that electrical wires may be easily connected to an external circuit from the lower electrode pad 150 and the upper electrode pad 170 of the piezoelectric structure 190.

The lower electrode 120 and the upper electrode 160 formed on the silicon base 180 has a single-layered or multi-layered conductive film, and the piezoelectric film 130 is interposed therebetween to form a pair of mutually isolated counter electrodes 120 and 160. The lower electrode 120 and the upper electrode 160 are electrically insulated from the silicon base 180 by the medium of an insulation film 111. Both the electrodes 120 and 160 collect electric charges generated by the piezoelectric film 130 through piezoelectric conversion in response to a change of mechanical strain.

One end of the lower electrode pad 150 is connected to the lower electrode 120 through a contact window 140, and one end of the upper electrode pad 170 is connected to the upper electrode 160. The electrode pads 150 and 170 transfer the electric charge collected by the electrodes 120 and 160 to an external circuit through fine electrical wires 260 and are insulated from the silicon base 180. The electrode pads 150 and 170 and the upper electrode 160 need to be formed of the conductive material.

A piezoelectric film material 113 configured to convert a change of mechanical strain applied to the piezoelectric micro power generator 100 in response to an external environment change into electric energy through piezoelectric conversion is formed of at least one of an inorganic material, an organic material, a nano material and a mixture thereof. For example, the piezoelectric film material 113 includes a metal nitride or a metal oxide such as aluminum nitride (AIN), zinc oxide (ZnO), BaTiO₃, lead zirconate titanate (PZT) (PbZrₓTi₁₋ₓO₃) and PMN-PT[₍₁₋ₓ₎Pb(Mg_{1/3}Nb_{2/3})O₃₋ₓPbTiO₃], an inorganic material such as ceramic, and an organic material such as polyvinylidene fluoride (PVDF), as well as a nano material such as a nano wire or a nano tube.

As described above, in the present disclosure, as a portion of the silicon bas 180 is coupled to the frame 220 having the opened cavity 230, the piezoelectric structure 190 to which the proof mass 200 is coupled is suspended, whereby a mechanical displacement may be generated in response to external vibrations and a mechanical strain corresponding to the mechanical displacement may be applied to the piezoelectric film 130. As the electric charges generated by the piezoelectric film 130 interposed between the lower electrode 120 and the upper electrode 160 forming the piezoelectric structure 190 are collected by using the electrodes 120 and 160 and are output to an external circuit, electric power is produced by the piezoelectric micro power generator itself.

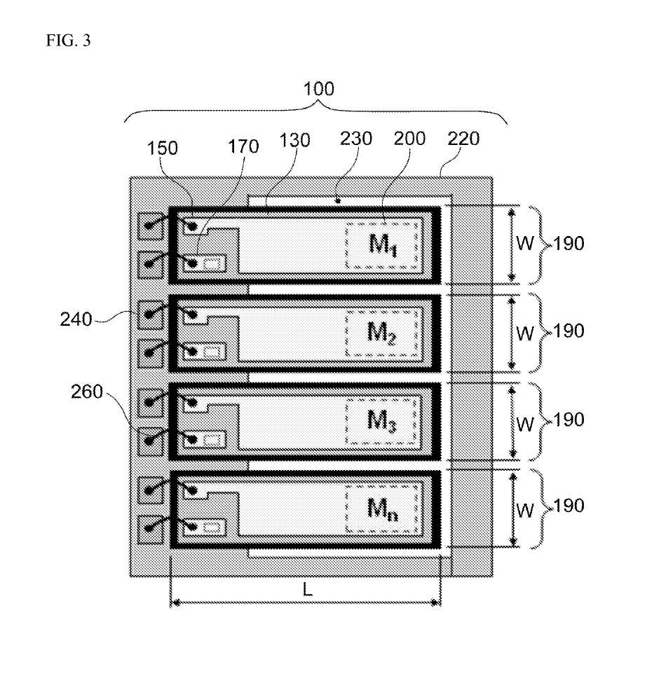

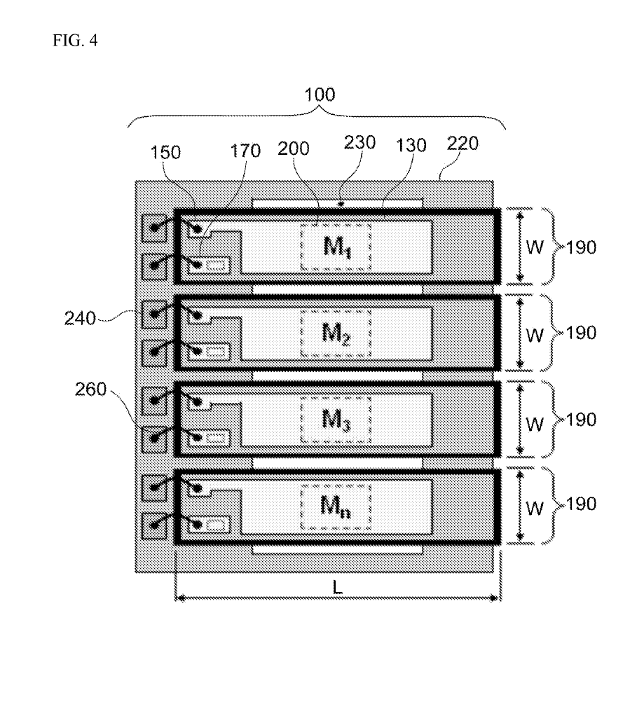

FIGS. 3 and 4 are plan views of the piezoelectric micro power generator 100 including a plurality of piezoelectric structures 190 in the form of a cantilever array and in the form of a bridge according to other exemplary embodiments of the present disclosure.

Referring to FIGS. 3 and 4, the piezoelectric micro power generator 100 may have a form where the plurality of piezoelectric structures 190 is coupled to and suspended by one frame 220. The features and characteristics of the piezoelectric structures 190 are the same as described with reference to FIGS. 1A to 2B.

Here, the response characteristics to an external vibration environment may be controlled by properly designing the width W and length L of the piezoelectric structure 190 and the masses M₁ to Mₙ of the proof masses 200.

In the piezoelectric structures 190, the two electrode pads 150 and 170 are connected to two electrical wire extracting parts 240 located in the frame 220 through the electrical wires 260. The piezoelectric structures 190 may be electrically connected in parallel or in series to be operated.

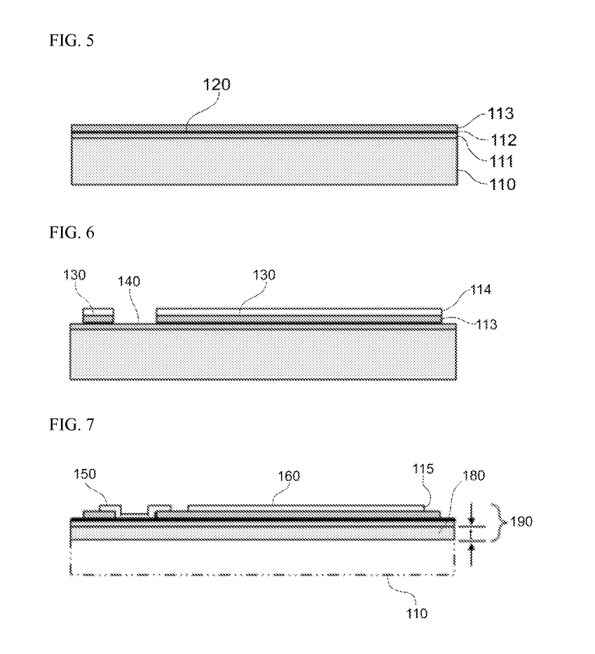

FIGS. 5 to 10 are process flowcharts illustrating a method of manufacturing a piezoelectric micro power generator according to an exemplary embodiment of the present disclosure. The fabrication method may include two semiconductor patterning process, a chemical mechanical polishing process, two bonding processes and a die separation process.

In describing the process of manufacturing a piezoelectric micro power generator according to the present disclosure with reference to FIGS. 5 to 10, the insulation film 111 is formed on a silicon substrate 110 first (see FIG. 5). Here, the insulation film 111 functions to electrically insulate the silicon substrates 110 and the like to minimize an influence of the currents flowing through the lower electrode 120, the upper electrode 160, the lower electrode pad 150, and the upper electrode pad 170 (see FIGS. 1A and 2A) formed in the following processes on the peripheral parts such as the silicon substrate 110.

The insulation film 111 may be formed of a non-conductive material such as silicon oxide film (SiO₂), a silicon nitride film (Si₃N₄), a modified silicon oxide film (SiO₂) and a low-stress silicon nitride film (Si_{X}N_{Y}). The insulation film 111 needs to be formed to have a thickness of 0.3 to 1 μm, and may be formed of a single layer, a stacked film, or several composite layers.

Next, a conductive film 112 used as the lower electrode 120 for collecting electric charges generated by the piezoelectric film 113 which is to be formed later is deposited on the insulation film 111. In order to deposit a metal film which is the conductive film 112, a stacked metal film in the form of a Ti/Pt film, a Ti/Mo film, a Ti/Au film or the like is formed by, through sputtering or e-beam evaporation, enhancing an adhesion property with the insulation film 111 first, depositing a Ti film, a TiW film, and a Cr film having a small thickness with a base layer functioning to block a constituent component of the conductive film 112 from being diffused to the peripheral parts, and depositing a Pt, Mo, or Au thin film having a thickness of 0.1 μm to 0.3 μm thereon for the purpose of promoting a crystal orientation of the piezoelectric film. In this case, another electrically conductive layer based on a metal such as TiN, TiO₂, Ta, TaN, Ti/TiN, Ti/Ni, Ti/TiW, and the like may be combined as the lower base layer additionally.

The piezoelectric film 113 is formed thereon and the piezoelectric film 113 may be formed through sputtering, chemical vapor deposition (CVD), printing, e-beam evaporation, pulsed laser deposition, a sol-gel process, and the like, and a piezoelectric film 113 made of an aluminum nitride film (AIN) forme ° C. d in a columnar and c-axis orientation to have a thickness of 1 μm through reactive sputtering at a substrate temperature of approximately 350° C. by using a aluminum target in an exemplary embodiment of the present disclosure will be described by way of example.

Next (see FIG. 6), an insulation film 114 is formed on the AIN piezoelectric film 113 for the purpose of a masking layer for etching, a photoresist (PR) (not illustrated) is micro-patterned through a photolithography process with a pattern mask after the PR is applied on the insulation film 114, and then the insulation film 114 is patterned through a reactive ion etching or wet etching method. Thereafter, while taking the patterned insulation film 114 as a masking layer for etching, the lower AIN piezoelectric film 113 is patterned to cover an active area 130 of the micro power generator element through reactive ion etching or a wet etching method using tetramethylammonium hydroxide (TMAH) or a phosphoric acid (H₃PO₄) solution, and the contact window 140 to the lower electrode is formed.

Next (see FIG. 7), after the insulation film for masking 114 is entirely removed, the PR (not illustrated) is applied, and after the PR is micro-patterned through a photolithography process with a pattern mask, a conductive film 115 is deposited on the entire upper surface of the PR through e-beam evaporation and the like. In this case, the conductive film 115 is deposited to have a thickness of not less than 0.3 to 0.5 μm by combining the metal materials (for example, Ti/Au) mentioned as the lower electrode material of FIG. 3. Next, through a lift-off process where only the pattern of the conductive film 115 is left by removing the PR with a solution, the upper electrode 160 and the upper electrode pad 170 (see FIGS. 1A and 2A) are formed on the active area 130 covered with the AIN piezoelectric film 113 and the lower electrode pad 150 is formed on the contact window 140. Thereafter, the silicon base 180 which is a basic structure having a predetermined thickness t is formed by thinning the bottom surface of the silicon substrate 110 through chemical mechanical polishing (for example, not more than 100 μm). The AIN piezoelectric structure 190 taking a silicon material as a support base 180 is fabricated through the above processes.

The following drawings illustrate to include three silicon based piezoelectric structures 190 at a wafer level to help understanding the fabrication processes.

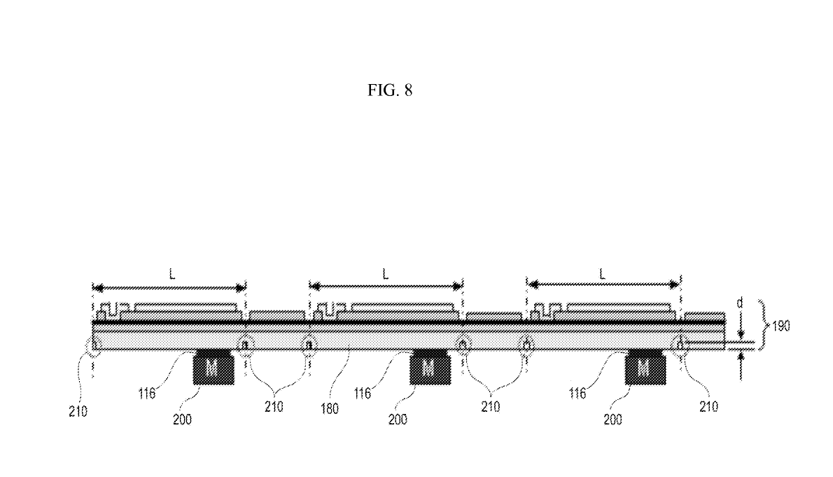

The next process is a process for bonding the proof mass 200 to the AIN piezoelectric structure 190 (see FIG. 8). The proof mass 200 is coupled through a bonding process where a stress is minimized. For example, after an insulating or conductive bonding material 116 is applied or titrated to the silicon base 180, the proof mass 200 is bonded and heat-treated at a proper temperature and in a proper atmosphere to be hardened and fixed. Alternatively, the proof mass 200 formed of an organic/inorganic material mixture may be formed directly on the bottom surface of the silicon base 180 by using a printing process.

Next, a die separating recess 210 is formed on the bottom surface of the silicon base 180 to have a predetermined depth d by dividing the entire wafer to have a predetermined width W and a predetermined length L in a two-axis direction of X-Y such that a plurality of AIN piezoelectric structures 190 is arranged at the entire wafer level. In this case, the process of forming the die separating recess 210 may include scribing, sawing, stealth dicing, and the like by using a thin blade or a laser beam.

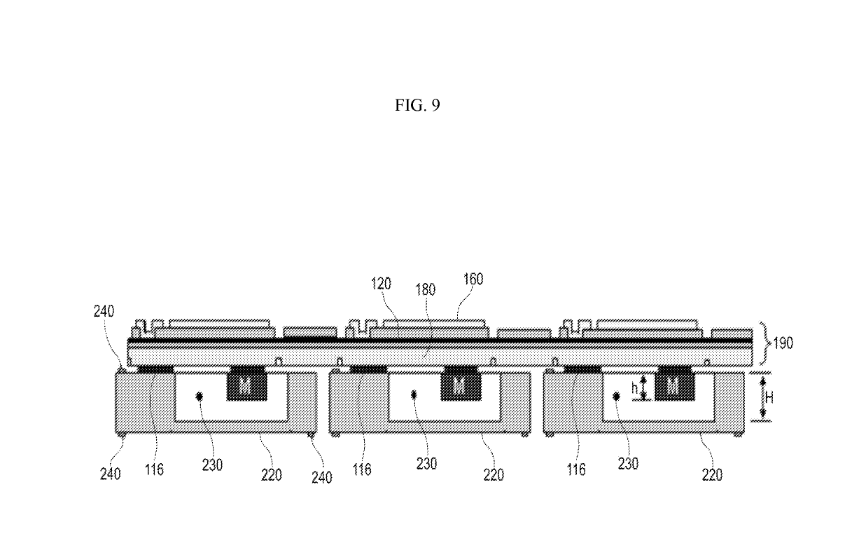

The next process is a process of coupling the piezoelectric structure 190 to which the proof mass 200 is attached to the frame 220 such that a dynamic mechanism is formed by fixing and supporting a portion of the silicon base 180 (see FIG. 9). For example, after the bonding material 116 is applied or titrated to the silicon base 180, a portion of the bottom surface of the silicon base 180 is coupled to the top surface of the frame 220 having the opened cavity 230 through the bonding process, and then is heat-treated at a proper temperature and in a proper atmosphere to be hardened and fixed. As the electrical wire extracting part 240 (see FIGS. 1A and 2A) is formed of a package material in the frame 220 in advance, the upper electrode 160 and the lower electrode 120 of the piezoelectric structure 190 are easily connected to an external circuit.

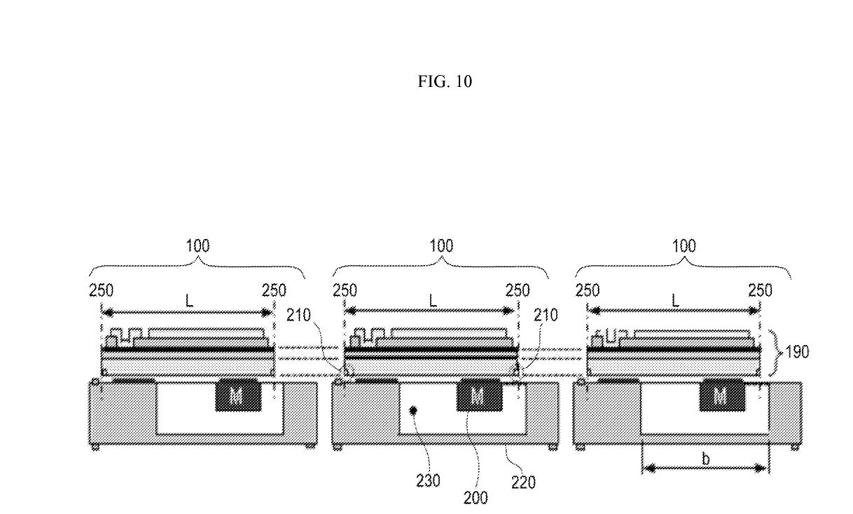

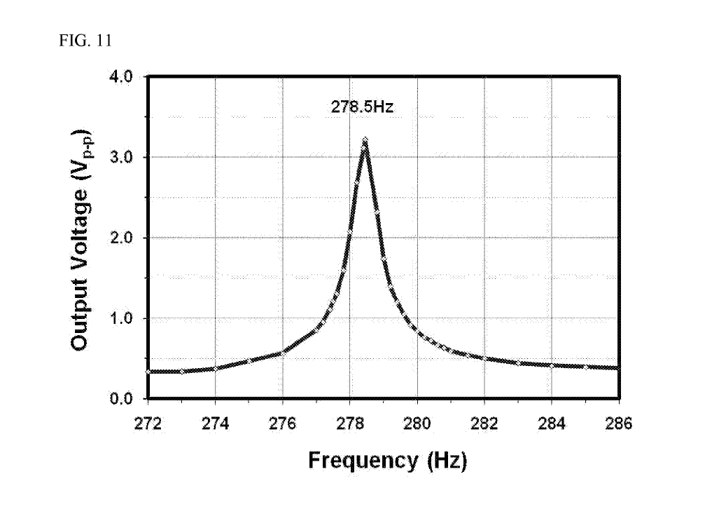

Next (see FIG. 10), dies are individually separated through a die separating part 250 such that the AIN piezoelectric unimorph structure 190 has a predetermined width W and a predetermined length L at the entire wafer level by using the die separating recess 210 formed in FIG. 8. Accordingly, a plurality of piezoelectric micro power generators 100 each having the finally suspended AIN piezoelectric structure 190 is fabricated.

As described above, all primary functional elements constituting a piezoelectric micro power generator 100 are formed through the fabrication processes of FIGS. 5 to 10.

Next, a wire bonding process for mutually connecting the electrical wire extracting part 240 formed on the frame 220 in advance and the upper electrode pad 170 and the lower electrode pad 150 of the AIN piezoelectric structure 190 by using the fine electrical wires 260 is performed. FIGS. 1A and 2B illustrate a piezoelectric micro power generator 100 when the electrical wires 260 have been connected.

According to the method of manufacturing a piezoelectric micro power generator of the exemplary embodiment of the present disclosure, primary functional elements constituting a piezoelectric micro power generator can be easily formed by a minimum number of fabrication steps through two semiconductor patterning processes, chemical mechanical polishing, two bonding processes, and die separation. Thus, manufacturing costs for the piezoelectric micro power generator can be reduced and the processes can be simplified.

By forming a suspension structure for a micro power generator through a substrate wafer polishing process, a bonding process, and a die separating process, a stiction phenomenon between a micro structure and a substrate occurring in the releasing process of removing a silicon oxide film as a sacrificial layer during a fabrication process for a conventional piezoelectric micro power generator can be originally removed, and a yield rate can be enhanced by reducing a damage to a device due to a stress generated during the fabrication process.

Proof masses having various types of properties and densities can be coupled to a silicon base through a bonding process or a printing process, and thus various vibration frequency bands can be utilized as a power generating source and a piezoelectric micro power generator structure capable of responding to an external vibration band having a low frequency even with a small-sized structure can be realized.

As package structures for suspending a structure of the piezoelectric micro power generator and extracting external electrical wires through a final die separating process are simultaneously finished, the piezoelectric micro power generator structure and the basic package structure are easily coupled to each other, which can reduce manufacturing costs and allows modified coupling of the piezoelectric micro power generator structure to another package structure.

FIG. 11 is a view illustrating electric power characteristics according to an external vibration frequency of a cantilever-type piezoelectric micro power generator according to an exemplary embodiment of the present disclosure by using an output voltage.

In the experimental piezoelectric micro power generator, the silicon base has a size of 10×20×0.1 mm³, the silicon proof mass at an end has a size of 10×10×0.55 mm³, and the effective electrode part has a size of approximately 5×8 mm². The resonance frequency of the micro power generator with respect to an acceleration of 1 G in the Z-axis direction shows 278.5 Hz, and the output voltage at a load resistance of 1 Mohm is 3.2 V (peak-to-peak) while the generated electric power calculated in rms shows 1.3 μW. Thus, it can be seen that the piezoelectric micro power generator according to the exemplary embodiment of the present disclosure is effectively fabricated and operated.

Although the technical spirit of the present disclosure has been described in detail with reference to the exemplary embodiments, it should be noted that the exemplary embodiments is for illustrating the description thereof and is not intended to limit the technical spirit of the present disclosure. It can be seen by those skilled in the art to which the present disclosure pertains that various embodiments can be made within the scope of the technical spirit of the present disclosure.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A piezoelectric micro power generator, comprising:
a piezoelectric structure having a silicon base, a lower electrode formed on the silicon base, a piezoelectric film formed on the lower electrode and configured to generate electric energy in response to a change of mechanical strain, an upper electrode formed on the piezoelectric film and a proof mass coupled to a portion of a bottom surface of the silicon base and configured to control response characteristics to vibration frequency; and
a frame having an opened cavity of a predetermined size and coupled to a portion of the bottom surface of the silicon base such that the proof mass is located within the cavity so as to suspend the piezoelectric structure.

2. The piezoelectric micro power generator of claim 1, wherein the piezoelectric structure is formed in the form of a cantilever by coupling only one portion of the bottom surface of the silicon base to the frame.

3. The piezoelectric micro power generator of claim 1, wherein the piezoelectric structure is formed in the form of a bridge by coupling two portions of the bottom surface of the silicon base to the frame.

4. The piezoelectric micro power generator of claim 1, wherein the lower electrode and the upper electrode form a pair of counter electrodes with the piezoelectric film being interposed therebetween.

5. The piezoelectric micro power generator of claim 1, wherein the piezoelectric film is formed of at least one of an inorganic material, an organic material, a nano material and a mixture thereof.

6. The piezoelectric micro power generator of claim 1, wherein the proof mass is formed of at least one of an inorganic material, an organic material, and a mixture thereof.

7. The piezoelectric micro power generator of claim 1, wherein the frame is formed of at least one of a PCB, ceramic, glass, a metal, plastic, silicon, or a mixture thereof.

8. The piezoelectric micro power generator of claim 1, further comprising:
a lower electrode pad and an upper electrode pad ends of which are connected to the lower electrode and the upper electrode, respectively and configured to transfer electric charge collected by the lower electrode and the upper electrode to the outside.

9. A piezoelectric micro power generator, comprising:
a piezoelectric structure array including a plurality of piezoelectric structures, each having a silicon base, a lower electrode formed on the silicon base, a piezoelectric film formed on the lower electrode and configured to generate electric energy in response to a change of mechanical strain, an upper electrode formed on the piezoelectric film and a proof mass coupled to a portion of a bottom surface of the silicon base and configured to control response characteristics to vibration frequency; and
a frame having opened cavities of a predetermined size and coupled to portions of the bottom surfaces of the silicon bases of the plurality of piezoelectric structures such that a plurality of proof masses coupled to the plurality of piezoelectric structures is located within the cavities so as to suspend the piezoelectric structure array.

10. The piezoelectric micro power generator of claim 9, wherein the plurality of piezoelectric structures is formed in the form of cantilevers by coupling only one portions of the bottom surfaces of the silicon bases to the frame.

11. The piezoelectric micro power generator of claim 9, wherein the plurality of piezoelectric structures is formed in the form of bridges by coupling two portions of the bottom surfaces of the silicon bases to the frame.

12. A method of manufacturing a piezoelectric micro power generator, comprising:
forming an insulation film on a silicon substrate;
forming a lower electrode, a piezoelectric film and an upper electrode on the insulation film;
polishing a bottom surface of the silicon substrate to form a silicon base;
forming a die separating recess on the bottom surface of the silicon base to divide the silicon base;
coupling a proof mass to a portion of the bottom surface of the silicon base;
coupling a portion of the bottom surface of the silicon base to a top surface of the frame having an opened cavity such that the proof mass is located within the cavity; and
separating the silicon base for dies by using the die separating recess.

13. The method of claim 12, wherein the piezoelectric film is formed by using at least one method of sputtering, chemical vapor deposition (CVD), e-beam evaporation, pulsed laser deposition, a sol-gel process, and printing.

14. The method of claim 12, wherein a thickness of the silicon base is controlled by using chemical mechanical polishing in the forming of the silicon base.

15. The method of claim 12, wherein the proof mass is coupled to the bottom surface of the silicon base by using a bonding or printing process.

16. The method of claim 12, wherein in the dividing of the silicon base, at the entire wafer level, the die separating recess is formed by performing scribing, sawing, and stealth dicing on the bottom surface of the silicon base at a predetermined depth.
